(19) United States
(12) Patent Application Publication
(10) Pub. No.: US 2014/0000512 A1
(43) Pub. Date: Jan. 2, 2014

(54) ROLLER COVER

(71) Applicants: Michael Clauss, Walenstadt (CH); Silvio Jaeger, Mauren (LI); Alexander Fornaro, Rapperswil (CH); Guido Castelmur, Sargans (CH); Liberato Raffaele, Trubbach (CH)

(72) Inventors: Michael Clauss, Walenstadt (CH); Silvio Jaeger, Mauren (LI); Alexander Fornaro, Rapperswil (CH); Guido Castelmur, Sargans (CH); Liberato Raffaele, Trubbach (CH)

(73) Assignee: OERLIKON SOLAR AG, TRUBBACH, Truebbach (CH)

(21) Appl. No.: 13/535,498

(22) Filed: Jun. 28, 2012

(51) Int. Cl. B65G 13/02; H01L 31/18

(52) U.S. Cl. 118/500; 198/780

(57) ABSTRACT

The invention relates to a roller drive device for use in a deposition system for manufacturing a photovoltaic device having a substrate (12), the roller drive device comprising a roller means (9) and a cover means (1), whereby the roller means is arranged slidable along a roller means axis (11) between a rolling position and a retracting position, whereby the roller means is configured for transporting the substrate in the rolling position, the cover means is arranged slidable along a cover means axis (2) between a shielding position and an opening position, whereby, if the roller means is in the retracting position, the cover means is configured for shielding the roller means against contamination by a substance present in the deposition system in the shielding position, and the roller means axis and the cover means axis are arranged tilted to each other.

### TECHNICAL FIELD

The present invention relates to the field of transporting a substrate in a deposition system. Particularly, the present invention discloses a device for improving process performance of a substrate deposition system.

### BACKGROUND ART

Photovoltaic devices, photoelectric conversion devices or solar cells are devices which convert light, especially sunlight into direct current electrical power. For low-cost mass production thin film solar cells are being of interest since they allow using glass, glass ceramics or other rigid or flexible substrates as a base material, i.e. as a substrate. The solar cell structure, i.e. the layer sequence responsible for or capable of the photovoltaic effect is being deposited in thin layers.

The deposition of said layers is typically done in a CVD system. The reactants, e.g. precursor materials, are being fed into process stations by a so called gas shower. The substrate, e.g. a workpiece to be treated, e.g. coated, is being placed and heated on a hot plate, i.e. a substrate carrier, to establish a preferred environment for the deposition on the surface of the substrate. Normally, at least a fraction of these reactants are deposited, whereas the residuals are being removed via exhaust means, e.g. a vacuum pump.

With conventional systems, the substrates are being transported horizontally through the system by sets of rollers, supporting the substrates from beneath. Typical substrates are rectangular or square sheets of glass, glass ceramics or crystalline glass, plastic or even metal. The rollers are usually actuated e.g. by motors via a driveshaft.

As these rollers are arranged within a process chamber, e.g. a process station of a CVD system, they are exposed to the process gases, such as reactants, precursor substances and respective reactants, and will thus get coated over time. This coating negatively influences the process performance of the system. Firstly, the rollers will get contaminated by the coating and during further use the coating on the roller will be transferred to the lower side of the substrates and will stick to it. Thus the performance of subsequent systems further treating the substrate is influenced negatively. Secondly, the coating of O-rings arranged on the roller for transporting the substrate will slowly build up and start to flake off at a certain film thickness. These flakes contaminate the process chamber and influence the coating of the substrates negatively.

Consequently, there exists a need for improving process performance of such systems.

### DISCLOSURE OF INVENTION

It is an object of the present invention to improve process performance of a substrate treatment system, particularly to improve the performance of a roller used in a substrate treatment system.

This object is solved by the independent claim. Advantageous embodiments are given in the dependent claims.

Thus, this object is achieved by a roller drive device for use in a deposition system for manufacturing a photovoltaic device having a substrate, the roller drive device comprising
a roller means and a cover means, whereby
the roller means is arranged slidable along a roller means axis between a rolling position and a retracting position, whereby the roller means is configured for transporting the substrate in the rolling position,
the cover means is arranged slidable along a cover means axis between a shielding position and an opening position, whereby, if the roller means is in the retracting position, the cover means is configured for shielding the roller means against contamination by a substance present in the deposition system in the shielding position, and
the roller means axis and the cover means axis are arranged tilted to each other.

Accordingly, it is an essential idea of the invention to cover the retracted roller means from being affected negatively by contamination resulting from the deposition process. Advantageously, the retracted roller means being shielded by the cover means is prevented against contamination by process gases, for example from precursor substances, respectively by their reaction products, used in a deposition system. For example, a TCO deposition system produces huge amounts of ZnO dust, which deposits within the deposition system, e.g. on inner walls of the deposition system as an unwanted dust deposition. Due to the movement of parts present in the deposition system, such as roller means for transporting the substrate, the deposition dust may chip off the walls and thus negatively influence the deposition process.

The invention now provides an advanced solution which allows for shielding the roller means by the cover means, whereby only very little space is required to actually implement the solution: As the roller means axis and the cover means axis are arranged tilted to each other, for example with an angle of 45°, any drive means required for actuating the roller means and/or the cover means to perform the sliding is arrangeable independently from each other in a manner that in sum only requires very little space while in parallel the uptime of the overall system in increased. Thus, the such shielded roller means does not negatively affect another substrate when becoming un-retracted again, i.e. slided from the retracting position into the rolling position to transport another substrate.

In sum, the invention avoids any negative influence arising from substances respectively their reaction products used in the deposition system and does also increase the performance level of subsequent systems further treating the deposited substrate. In this way, contamination cannot reach the surface of the roller means when being shielded by the cover means.

The term “slidable” means preferably that the roller means respectively the cover means is moveable along a linear axis from a first position into a second position and back again. In the rolling position a substrate to be treated in the deposition system is placeable onto the roller means and thus moveable by the roller means within the deposition system, e.g. from a first processing station to a second processing station. In the retracting position the roller means is preferably arranged such that the substrate is not placeable anymore on the roller means. Preferably, the cover means is configured such that the cover means can only slide from the opening position into the shielding position when the roller means is in the retracting position. As an example, the distance between the rolling position and the retracting position and/or between the shielding position and the opening position may be 20 cm or 50 cm. The term “tilted to each other” means preferably that the roller means axis and the cover means axis are not arranged parallel to each other and comprise an angle to each other that is greater than 0°. “Tilted” might be replaceable by the term “twisted”. More preferably the roller means axis and the cover means axis are arranged distant to each other.

In a preferred method for transporting the substrate by the roller means, first the cover means slides from the shielding position into the opening position. Then, the roller means slides from the retracting position into the rolling position such that the substrate is placeable onto the roller means. Once the transport is finished, the roller means may slide from the rolling position into the retracting position such that thereafter the cover means may slide from the opening position into the shielding position for shielding the retracted roller means.

Preferably, a plurality of roller means, and respective cover means, are situated in such manner within the deposition system that one part of the roller means is arranged on one side of the substrate and another part of the roller means is arranged on the other side of the substrate. In another embodiment, the substrate is only contacted from the rear side on its lower surface. Once the substrate has arrived in a desired position, being transported by the roller means, a substrate support, e.g. a hot table, is being elevated from a lower position to lift the substrate from the roller means.

Preferably, the deposition system is selected from the group consisting of a CVD system, a PVD system, a PECVD system, an APCVD system and/or a MOCVD system. Most preferably, the deposition system is a “TCO1200” supplied by Oerlikon Solar, as known in the art. The “TCO 1200” is a linear inline LP-CVD system with process stations arranged linearly subsequently in a row. It is furthermore preferred that the roller means is arranged within the deposition system, e.g. within a process chamber of the deposition system and/or such that at least the roller means and/or the cover means extend into the process chamber, e.g. when sliding into the opening position respectively the rolling position. The roller means may be provided as any suitable means for transporting a substrate in the deposition system, such as a belt or a substrate support means, and may comprise a roller attached to an axis forming the roller means axis, whereby the roller contacts the substrate on its outer surface such that the roller comprises at least one part that extends orthogonal to the extension of the surface of the substrate. The substrate can be any suitable substrate known from prior art, which is usable for manufacturing a thin-film photovoltaic device or at least a part of a thin-film photovoltaic device, for example glass. Preferably the pressure regime in the deposition system can vary, depending on the process, between near atmospheric conditions, e.g. a few hundred hPa, to vacuum conditions, e.g. 10⁻¹ to 10⁻⁵ hPa.

According to a preferred embodiment, the roller means and the cover means are configured such that the roller means is only slidable between the rolling position and the retracting position if the cover means is in the opening position. In other words, the cover means, when in the shielding position, prevents that the roller means is slidable between the rolling position and the retracting position.

Generally, the roller means axis and the cover means axis, which preferably extend to each other as linear axes and are crossed to each other, may be tilted with any angle greater than 0° to each other. In a preferred embodiment the angle is ≧30° and ≦90°. However, according to another preferred embodiment, the roller means axis and the cover means axis are arranged with an angle of 45° or 90° tilted to each other. Other angels might be, for example, 25°, 30°, 40°, 50° or 60°. In another embodiment the angle is variable. Placing the roller means axis and the cover means axis tilted to each other, preferably with an angle of 45°, is especially advantageous as the roller means and the cover means may slide independent from each other back and forth. In case the substrate is placed on the topside of the roller means, an angle between roller means axis and the cover means axis is preferred that allows for sliding the cover means from the opening position into the shielding position in a direction towards to topside of the roller means and/or towards the substrate. In other words, it is preferred that the cover means is arranged in its shielding position “beneath” the substrate when being placed on the roller means.

According to another preferred embodiment, the cover means is configured for shielding a plurality of roller means. Advantageously, for example, only one cover means is sufficient for shielding all roller means required for transporting the substrate. Thus, the solution allows for a simple and cost efficient shielding of the roller means by one single cover means.

According to another preferred embodiment, the cover means comprises a cover head and a quick change means, and the cover head is attached to the cover means by the quick change means. Preferably, the cover head comprises two sides, an outer side and an inner side, wherein the inner side is attached to the cover means axis such that in the shielding position the inner side is also shielded against contamination. As the outer side of the cover means is therefore exposed to contamination, the quick change means allows for a very simple detachment of the cover head such that the cover head can be cleaned, for example outside of the deposition system, and thereafter again attached to the cover means in a very simple manner. The terms “cover means axis” and/or “rolling means axis” first describe an axis along which the respective means is slidable. Furthermore, the respective axis may also comprise a metal bar or other comparable means, which forms the respective axis, for example as a piston rod of a pneumatic cylinder.

The cover head is preferably provided as a flap, as an enclose shielding, as a barrier, as a plate and/or may comprise a rectangular or rounded form. More preferably, the cover means and/or the cover head comprises a material that is resistant against substances and reaction products of the substances used in photovoltaic device manufacturing, as e.g. aluminum or metal. In another embodiment, the cover means and/or the cover head is configured for completely covering and/or shielding the retracted roller.

According to a further preferred embodiment, the roller means is arranged such that the substrate is transportable on the topside of the roller means and the cover means is arranged such that the opening position, starting from the shielding position, is reachable by sliding the cover means in the direction of the topside of the roller means. For example, in case of an angle of 45°, this means that the cover means is arranged such that the cover means is slidable from beneath the substrate, when arranged onto the roller means in the deposition system, with said angle of 45° relative to the surface of the substrate towards the topside of the roller means for reaching the opening position. In another preferred embodiment, the roller means and the cover means respectively the roller means axis and the cover means axis are arranged distant to each other, whereby the roller means axis and the cover means axis preferably span a plane that is orthogonal to the surface of the substrate, when arranged on the roller means.

According to another preferred embodiment, the roller drive device comprises a housing, whereby the cover means is completely arranged within the housing. Preferably, the cover means is also completely slidable within the housing from the shielding position to the opening position. Such an embodiment has the advantage, that the cover means is even better protected against contamination from substances respectively reactant products of the substances present in the deposition system.

In another preferred embodiment, the roller drive device comprises a motorized means for sliding the roller means and/or the cover means. Such motorized means may comprise any mechanical, electrical or pneumatic means known from the art, for example a pneumatic cylinder that allows for extending back and the forth the roller means respectively the cover means along the roller means axis respectively the cover means axis.

In another preferred embodiment, the roller drive device comprises a receiving element having an opening and the roller means comprises a roller head configured for transporting the substrate, whereby the roller head is arranged inside the receiving element in the retracting position and the cover means is configured for sealing the opening in the shielding position. Preferably, the receiving element is provided as a leakproof receiving element. More preferably, the roller head respectively the roller means is configured such that the rolling head is outside of the receiving element in the rolling position. In other words, the roller means is preferably configured such that the roller head is slidable from inside the receiving element in the retracting position through the opening towards and area outside of the receiving element for transporting the substrate. The receiving element may comprise a housing and might be configured, for example as a cave, such that the roller head is retractable back from the rolling position into the cave, which is then lockable by the cover means such that the roller head is protected against contamination. In another embodiment, the roller head comprises a board-wheel for guiding the substrate. Such receiving element does advantageously may protect the roller means respectively the roller head against contamination.

In another preferred embodiment, the cover means comprises an O-ring sealing configured for leakproof sealing the opening in the shielding position. Preferably, the O-ring is attached at an inner side of the cover means directing towards the roller means in the shielding position respectively in the retracting position. In another embodiment, the O-ring is configured for sealing the opening, i.e. configured for acting as a diffusion barrier. More preferably, plurality of O-rings is attached to the cover means.

In another embodiment, the roller drive device comprises a pressure change means for evacuating the receiving element and/or for creating an overpressure within the receiving element. In case the receiving element is locked by the cover means, evacuating the receiving element has the advantage that the sealing is improved, whereby any process gases might be additionally exhausted, which further improves the lifetime of the roller means. Creating an overpressure has the advantage that the intrusion of process gases into the receiving element can be avoided, e.g. as the overpressure creates a purging of the receiving element. In case the cover means axis is arranged with an angle of for example 45° against ground, attaching the sealing at the inner side of the cover means has a further advantage that any contamination present on the O-ring sealing may slip down due to gravity.

In another preferred embodiment, the roller drive device comprises a sensor element for monitoring the sliding of the roller means, whereby the sensor element is arranged inside and/or outside of the receiving element such that the acceptance cone, e.g. the witness and/or detection range, of the sensor element aims at, respectively directs into, the receiving element in direction of the roller means axis. The sensor element may comprise a hall sensor and/or an optical sensor. In case the sensor element is arranged outside of the receiving element, a glass plate might be foreseen between the sensor and the receiving element such that the acceptance cone of the sensor element can direct in direction of the roller means axis and such that the receiving element is still leakproof for creating a vacuum and/or overpressure. Such solution has the advantage that the sensor cannot be contaminated by process gases.

The object of the invention is further addressed by a deposition system for manufacturing a photovoltaic device comprising the roller drive device as discussed before, whereby the substrate is arrangeable onto the roller means such that the substrate surface extends into a direction parallel to the roller means axis. Such embodiment advantageously increases the uptime of the deposition system as the roller means is protected against contamination occurring by substances used in the deposition system. Such substances can be any substances present in a deposition system preferably for photovoltaic device manufacturing and might be a precursor substance and/or a reaction product of the precursor substance, for example selected from a group consisting of pyrophoric metal organic chemicals, phosphine, diborane, silane, dimethylzinc and/or diethylzinc. A reaction product of the substance therefore might be pyrophoric metal organic chemicals, phosphine, diborane, silane, dimethylzinc and/or diethylzinc. For example, the reaction product can be zinc, zinc oxide and/or doped zinc oxide, or any other metallic or oxidic deposition resulting from the deposition process and/or present in the deposition system.

In another embodiment, the deposition system is configured for manufacturing a thin-film photovoltaic device. In a further embodiment, the deposition system is used for thin-film deposition, more preferably for ZnO thin-film deposition. The deposition may take place under atmospheric or vacuum conditions. In a further embodiment the deposition system is used for the deposition of thin layers, whereby the substrate respectively the photovoltaic devices may have a size of 1.1 m×1.3 m.

### BRIEF DESCRIPTION OF DRAWINGS

These and other aspects of the invention will be apparent from and explained with reference to the embodiments described hereinafter.

In the drawings:

FIG. 1 shows a roller drive device with a cover means in opening position according to a preferred embodiment of the invention in a side-view,

FIG. 2 shows the roller drive device with the cover means in the shielding (“closed”) position according to the preferred embodiment of the invention in a side-view,

FIG. 3 shows the roller drive device with the cover means in the opening position according to the preferred embodiment of the invention in a top-view (rollers themselves omitted),

FIG. 4 shows the roller drive device with a roller means and the cover means according to the preferred embodiment of the invention in a side-view, whereby the roller means is in the rolling position,

FIG. 5 shows a roller drive device with the roller means and a cover means according to the preferred embodiment of the invention in a side-view, whereby the roller means is in the retracting position,

FIG. 6 shows a partial view of the roller drive device with the roller means and a cover means according to the preferred embodiment of the invention in a side-view, whereby the cover means is in the retracting position,

FIG. 7 shows a roller drive device according to another preferred embodiment of the invention in a side-view,

FIG. 8 shows the roller drive device according to a further embodiment of the invention in a side-view, and

FIG. 9 shows the roller drive device according to another preferred embodiment of the invention with a sensor element.

### DETAILED DESCRIPTION OF DRAWINGS

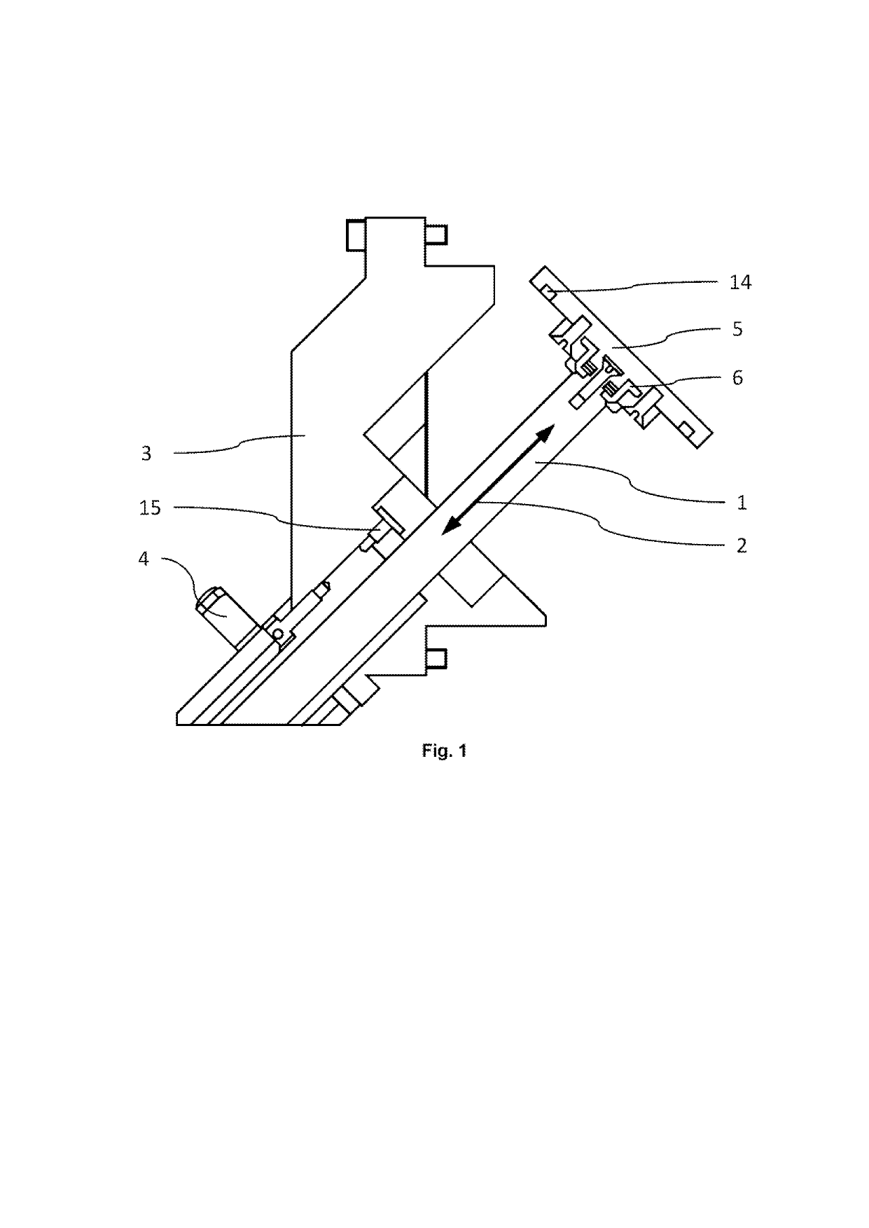

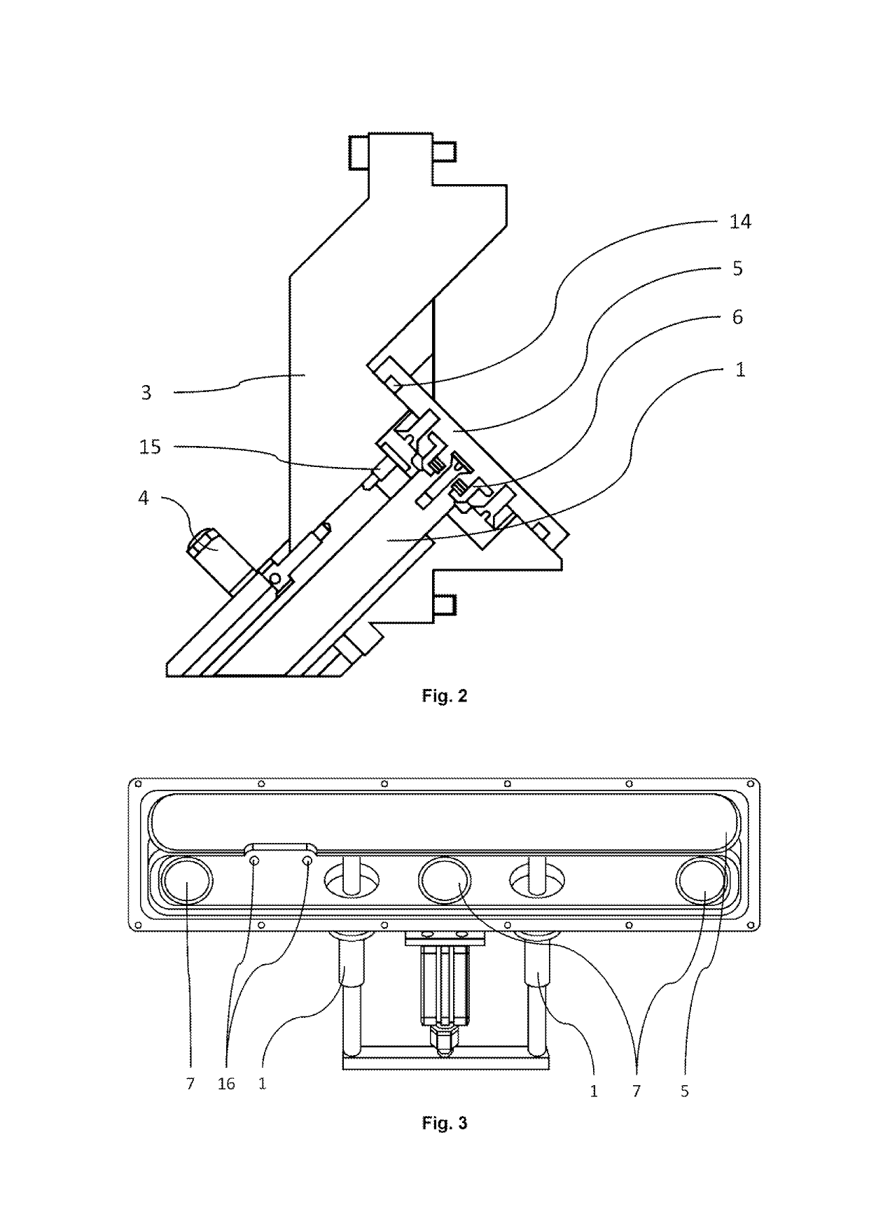

FIGS. 1 to 9 show a roller driver device for use in a deposition system for manufacturing a photovoltaic device. The roller drive device comprises a cover means 1 which is slidable along a cover means axis 2 from an opening position, shown in FIG. 1, into a shielding position, shown in FIG. 2.

The cover means is attached to a housing 3 of the roller drive device, whereby a motorized means 4 is arranged for sliding the cover means 1 between the shielding position and the opening position. Furthermore, the cover means 1 comprises a cover head 5 which is attached to the cover means 1 by a quick change means 6 for quickly removing the cover means head 5 and exchanging to another cover means head 5.

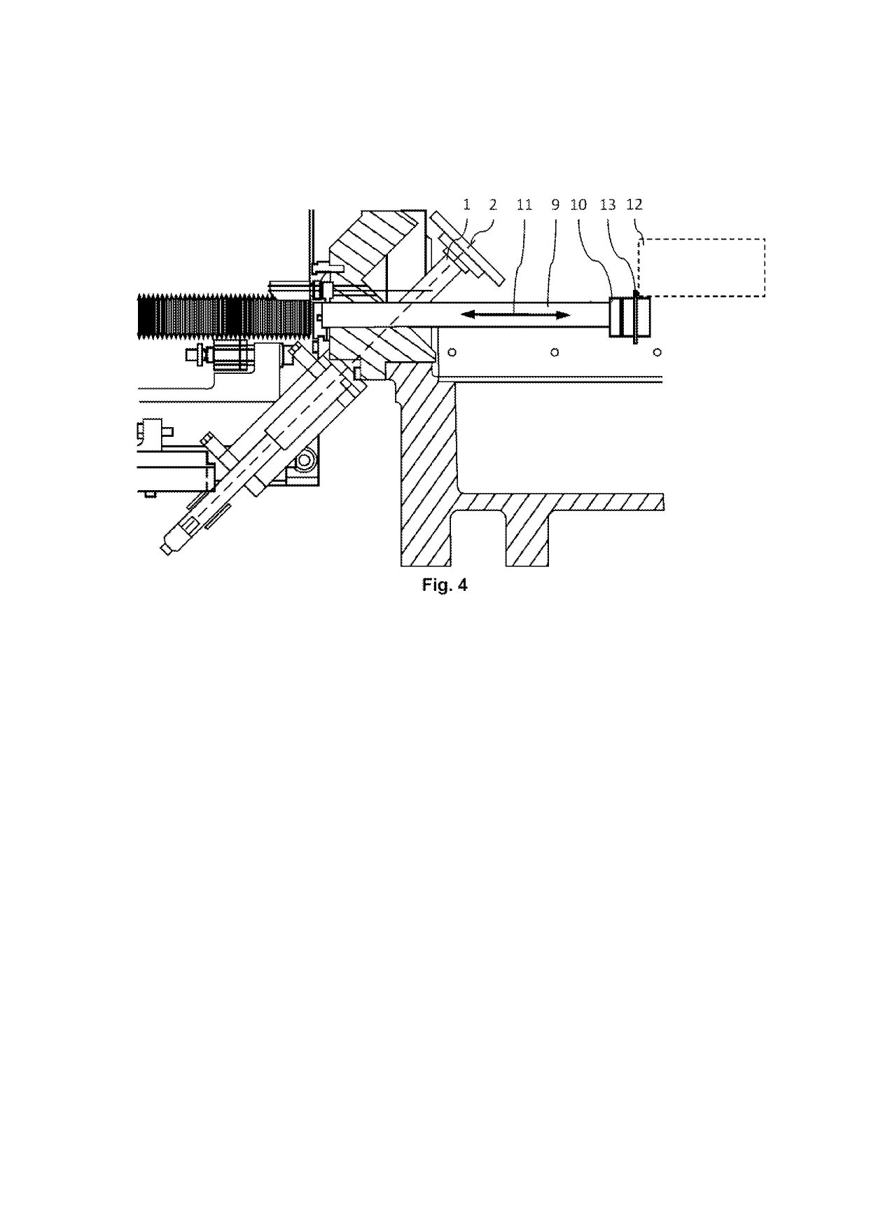

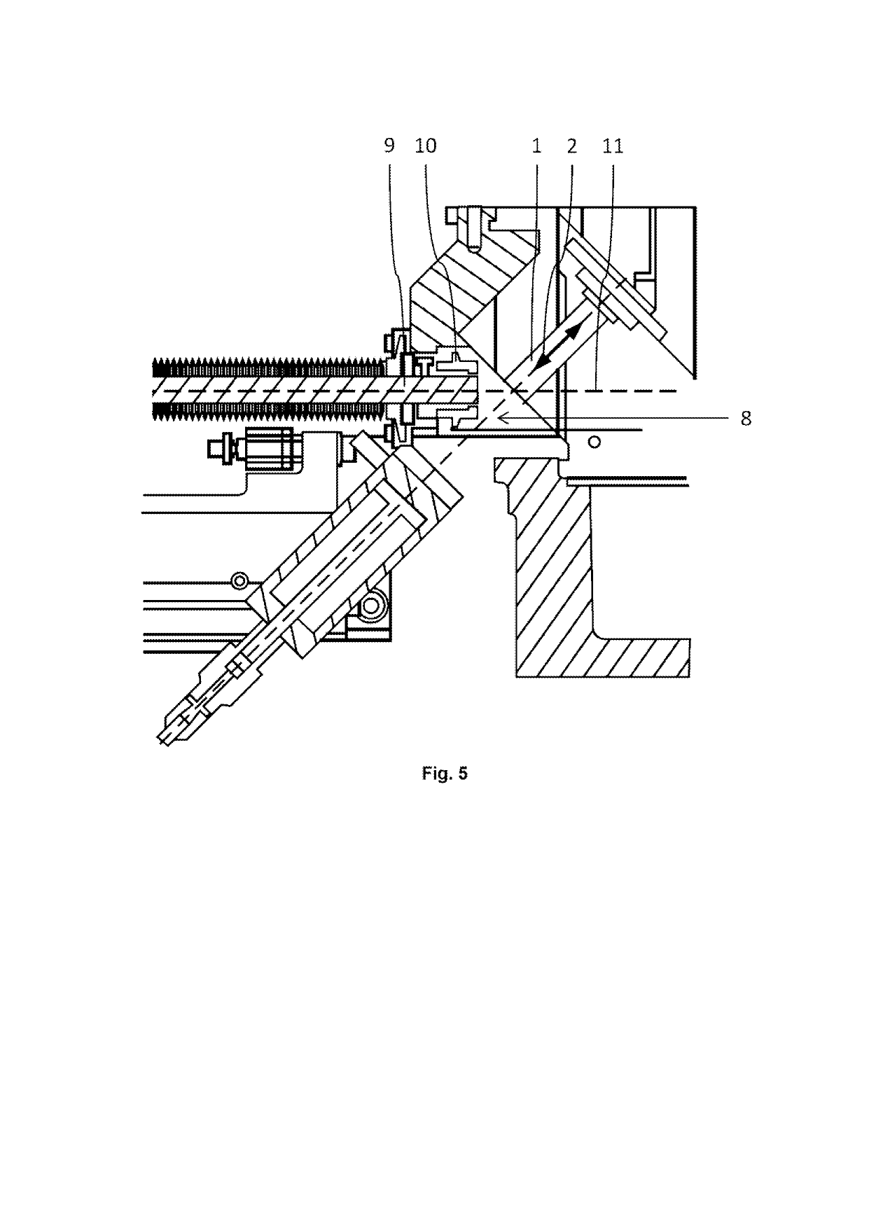

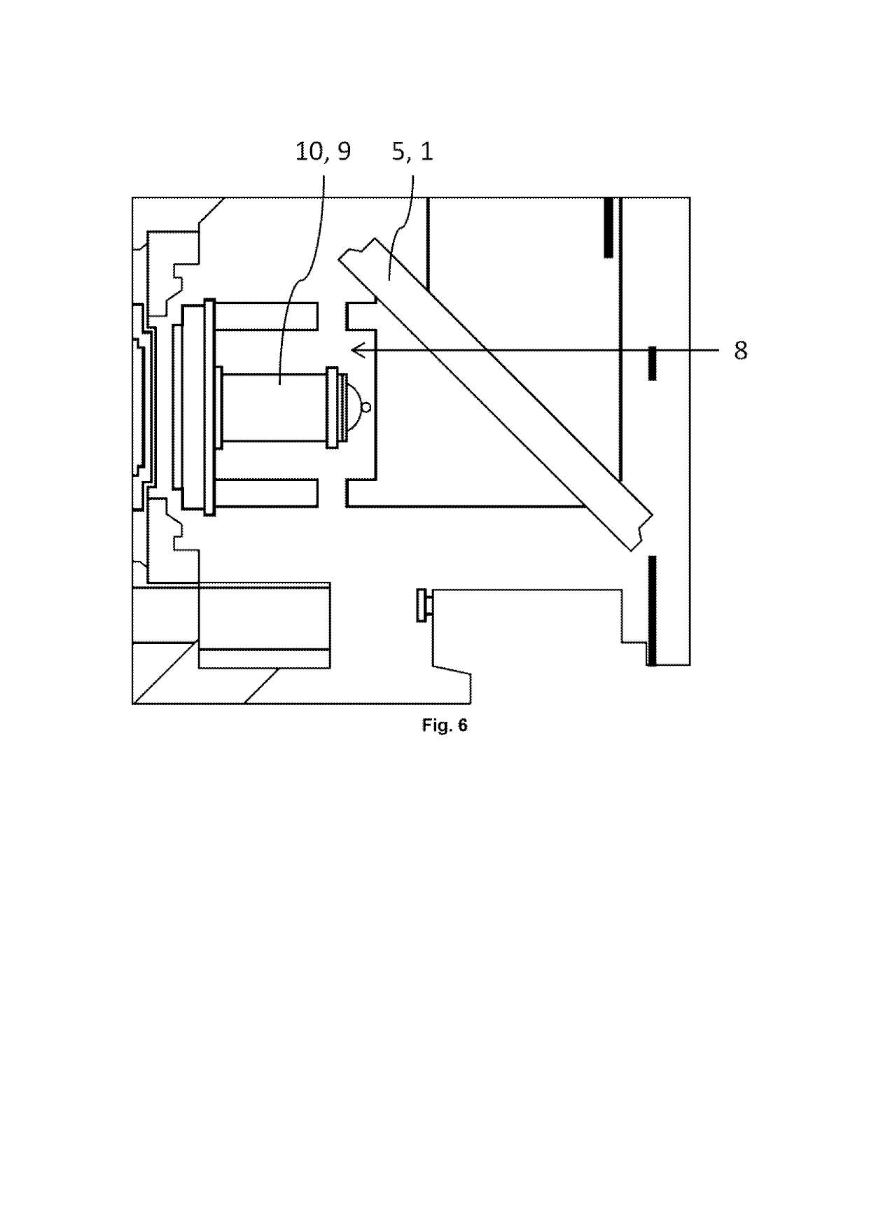

As can be seen from FIG. 3, one single cover means head 5 is connected to two cover means axes 2 having each a motorized means 4 such that the single cover head 5, if the cover means 1 is in the shielding position, protect three openings 7. The opening 7 each refer to a receiving element 8, which can be provided as a leakproof receiving element, whereby a roller means 9 is attached to the housing 3 respectively configured such that a roller head 10 of the roller means 9 is arranged in a retracting position, shown in FIG. 5, within the receiving element 8 and, as shown in FIG. 4, slided from the retracting position through the opening 7 along a roller means axis 11 into a rolling position. In the rolling position, a substrate 12 is placeable onto the roller head 10 such that the substrate 12 is transportable by the roller head 10 through the deposition system, for example to another process step. For further guiding the substrate 12, the roller head 10 comprises a board-wheel 13.

As can be seen from FIG. 3, the roller means 9 and the cover means 1 respectively the roller means axis 11 and the cover means axis 2 are arranged distant to each other and furthermore are arranged tilted to each other with an angle of 45°, first to each other and secondly in regard to the cover means axis 2 in regard to ground. This means that for sliding the roller means 9 from the retracting position into the rolling position, first the cover means 1 has to slide from the shielding position into the opening position, such that then the roller means 9 may slide into the rolling position.

Once the substrate 12 is transported by the roller means 9, the roller means 9 might be retracted back into the retracting position. Sliding back the cover means 1 into the shielding position, as shown in FIG. 6, the cover means 1 respectively the cover head 5 shields the roller means 9 against contamination by a substance present into the deposition system, respectively against contamination by a reaction product of the substance. This means that in the shielding position of the cover means 1 the roller means 9 is protected such that the lifetime of the roller means 9 is improved compared to prior art systems.

The cover head 5 further comprises an O-ring sealing 14 such that in the shielding position the opening 7 is leakproof shielded by the cover head 5. The O-ring sealing 14 is attached at the side of the cover head 5 that directs towards the motorized means 4 respectively away from the deposition chamber of the deposition system.

For evacuating the receiving element 8 and/or creating an overpressure within the receiving element 8 a pressure change means 15, for example a pump, is provided.

The roller drive device further comprises a sensor element 16, as shown in

FIG. 3 and FIG. 9, which is configured for monitoring the sliding of the roller means 9. Therefore, the sensor element 16 is arranged outside of the receiving element 8 and separated from the receiving element 8 by a glass plate such that the acceptance cone 17 directs through the receiving element 8 in direction of the roller means axis 11.

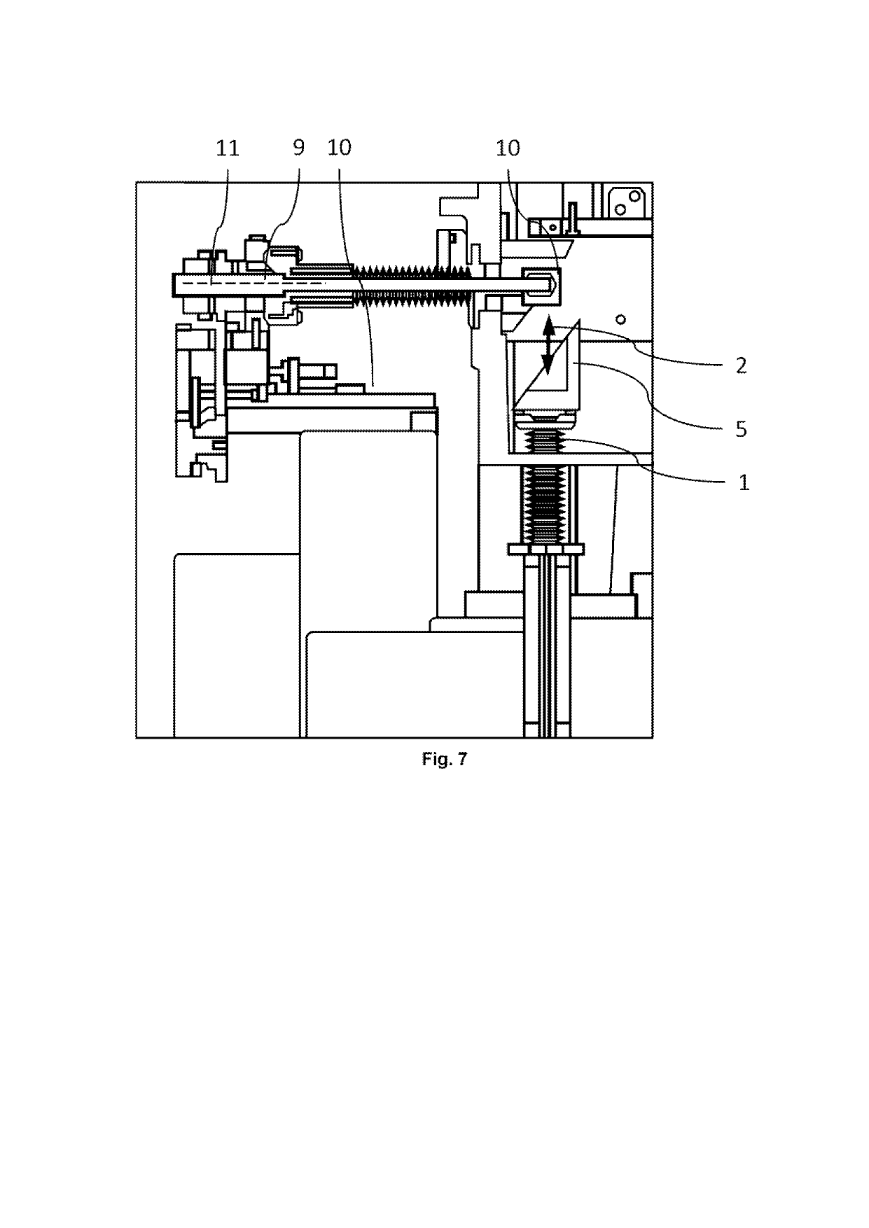

FIG. 7 shows a further embodiment wherein the angle between the roller means axis 11 and the cover means axis 2 is 90° and whereby the cover means 1 thus covers the retracted roller means 9 from “underneath” the substrate 12 i.e. slides from the opening position towards the shielding position from underneath the substrate in direction of the substrate.

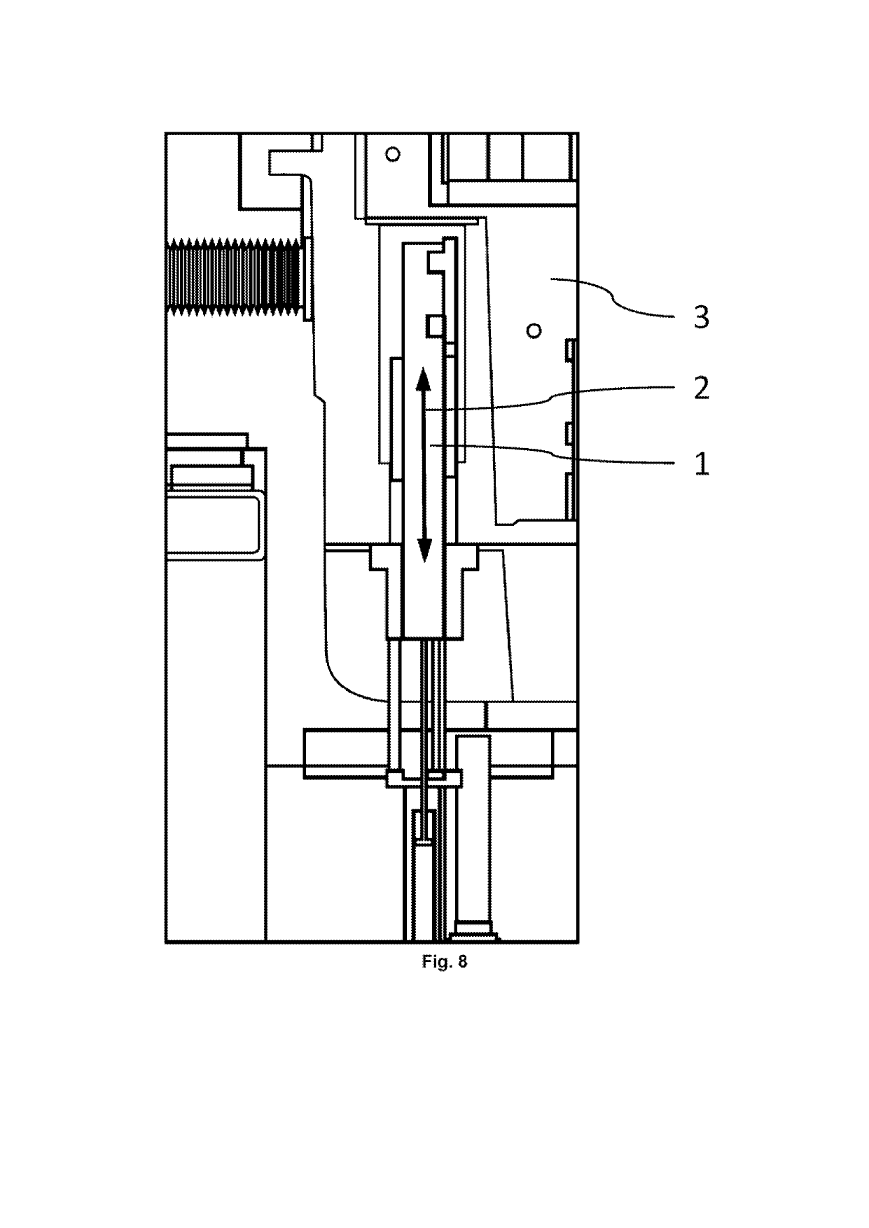

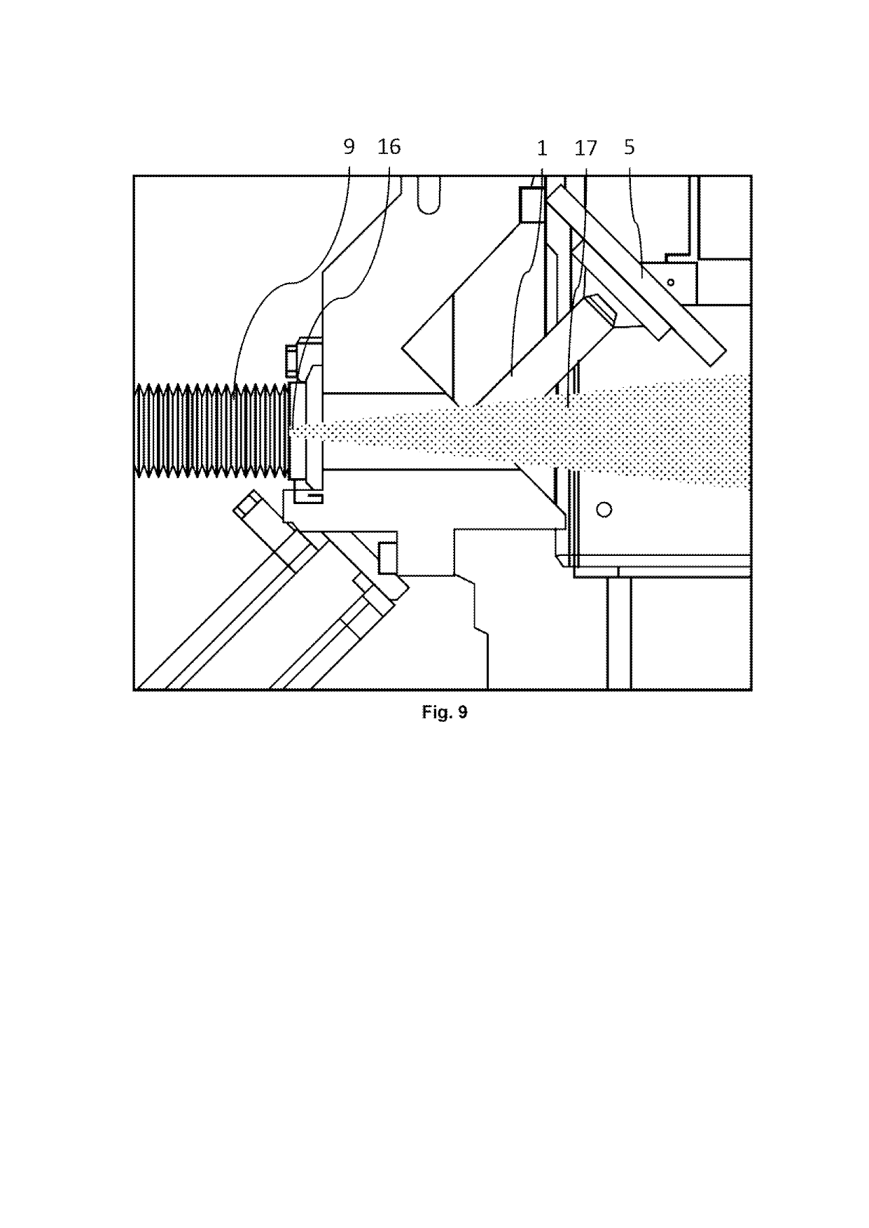

In an alternative embodiment, shown in FIG. 8, the cover means 1 is completely integrated into the housing 3 and arranged with an angle of 90° towards the roller means 9 respectively the cover means axis 2 is arranged with an angle of 90° to the roller means axis 11.

While the invention has been illustrated and described in detail in the drawings and foregoing description, such illustration and description are to be considered illustrative or exemplary and not restrictive, the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “ an” does not exclude a plurality. The mere fact that certain measures are recited in mutually different dependent claims does not indicate that a combination of these measures cannot be used to advantage. Any reference signs in the claims should not be construed as limiting the scope.

### REFERENCE SIGNS LIST

1 cover means
2 cover means axis
3 housing
4 motorized means
5 cover head
6 quick change means
7 opening
8 receiving element
9 roller means
10 roller head
11 roller means axis
12 substrate
13 board-wheel
14 O-ring sealing
15 pressure change means
16 sensor element
17 acceptance cone

1. Roller drive device for use in a deposition system for manufacturing a photovoltaic device having a substrate (12), the roller drive device comprising
a roller means (9) and a cover means (1), whereby
the roller means is arranged slidable along a roller means axis (11) between a rolling position and a retracting position, whereby the roller means is configured for transporting the substrate in the rolling position,
the cover means is arranged slidable along a cover means axis (2) between a shielding position and an opening position, whereby, if the roller means is in the retracting position, the cover means is configured for shielding the roller means against contamination by a substance present in the deposition system in the shielding position, and
the roller means axis and the cover means axis are arranged tilted to each other.

2. Roller drive device according to claim 1, whereby the roller means and the cover means are configured such that the roller means is only slidable between the rolling position and the retracting position if the cover means is in the opening position.

3. Roller drive device according to claim 1, whereby the roller means axis and the cover means axis are arranged with an angle of ≧30° and ≦60° tilted to each other.

4. Roller drive device according to claim 1, whereby the roller means axis and the cover means axis are arranged with an angle of 45° or 90° tilted to each other.

5. Roller drive device according to claim 1, whereby the cover means is configured for shielding a plurality of roller means.

6. Roller drive device according to claim 1, whereby the cover means comprises a cover head (5) and a quick change means (6), and the cover head is attached to the cover means by the quick change means.

7. Roller drive device according to claim 1, whereby the roller means is arranged such that the substrate is transportable on the top side of the roller means and the cover means is arranged such that the opening position, starting from the shielding position, is reachable by sliding the cover means in the direction of the top side of the roller means.

8. Roller drive device according to claim 1, comprising a housing (3), whereby the cover means is completely arranged within the housing.

9. Roller drive device according to claim 1, comprising a motorized means (4) for sliding the roller means and/or the cover means.

10. Roller drive device according to claim 1, comprising a receiving element (8) having an opening (7) and the roller means comprising a roller head (10) configured for transporting the substrate, whereby the roller head is arranged inside the receiving element in the retracting position and the cover means is configured for sealing the opening in the shielding position.

11. Roller drive device according to claim 9, whereby the cover means comprising an O-ring sealing (14) configured for leakproof sealing the opening in the shielding position.

12. Roller drive device according to claim 9, comprising a pressure change means (15) for evacuating the receiving element and/or creating an overpressure within the receiving element.

13. Roller drive device according to claim 9, comprising a sensor element (16) for monitoring the sliding of the roller means, whereby the sensor element is arranged inside and/or outside of the receiving element such that the acceptance cone (17) of the sensor element aims at the receiving element in direction of the roller means axis.

14. Deposition system for manufacturing a photovoltaic device comprising the roller drive device according to claim 1, whereby the substrate is arrangeable onto the roller means such that the substrate surface extends into a direction parallel to the roller means axis.

15. Deposition system according to claim 13, whereby the deposition system is configured for manufacturing a thin-film photovoltaic device.
